(19) United States
(12) Patent Application Publication
(10) Pub. No.: US 2013/0022743 A1
(43) Pub. Date: Jan. 24, 2013

(54) VAPOR GROWTH APPARATUS AND VAPOR GROWTH METHOD

(71) Applicants: Yoshikazu MORIYAMA, Shizuoka-ken (JP); Yuusuke Sato, Tokyo (JP)

(72) Inventors: Yoshikazu MORIYAMA, Shizuoka-ken (JP); Yuusuke Sato, Tokyo (JP)

(21) Appl. No.: 13/551,795

(22) Filed: Jul. 18, 2012

(30) Foreign Application Priority Data
Jul. 20, 2011 (JP) 2011-158582

(51) Int. Cl. C23C 16/52

(52) U.S. Cl. 427/248.1; 118/712

(57) ABSTRACT

A vapor growth apparatus according to an aspect of the present invention includes a reaction chamber into which a wafer is loaded, a first valve which is connected to the reaction chamber and controls a flow rate of a first exhaust gas discharged from the reaction chamber, a first pump which is provided on a downstream side of the first valve and discharges the first exhaust gas, a first pressure gauge which detects a first pressure that is a pressure of the reaction chamber, a first pressure control unit which controls the first valve based on the first pressure, a second pressure gauge which detects a second pressure that is a pressure between the first valve and the first pump, and a second pressure control unit which controls an operation volume of the first pump based on the first pressure and the second pressure.

### CROSS-REFERENCE TO RELATED APPLICATION

This application is based upon and claims the benefit of priority from the prior Japanese Patent Application No. 2011-158582 filed on Jul. 20, 2011, the entire contents of which are incorporated herein by reference.

### BACKGROUND OF THE INVENTION

The present invention relates to a vapor growth method and a vapor growth apparatus which are, for example, used for performing film formation on a semiconductor wafer.

For example, there is a single wafer processing type of the vapor growth apparatus used in a film forming process, which performs film formation on a wafer through a backside heating scheme in which while a wafer is rotated at a high speed of 900 rpm or more in a reaction chamber, a process gas is supplied thereon and the wafer is heated from the backside thereof using a heater.

When such a film formation is performed, a surplus process gas, reaction by-products, and the like are discharged from the reaction chamber using a vacuum pump. At this time, the pressure inside the reaction chamber is regulated to be a predetermined pressure using a throttle valve provided between the reaction chamber and the vacuum pump.

In this way, the pressure is controlled by the throttle valve, so that pressure can be controlled stably. On the other hand, the vacuum pump, is always operated in a full load state, and thus there is a problem in that power consumption increases.

When the pressure regulation is performed by controlling the rotation frequency of the vacuum pump in order to suppress the power consumption of the vacuum pump, in a case where the pressure inside the reaction chamber is high, the rotation frequency of the pump falls and the pressure regulation becomes unstable. If the rotation frequency of the dry pump does not reach some degree, the exhausting becomes unstable. However, in a case where the pressure inside of the reaction chamber is high, the dry pump may be operated well with an exhausting performance lower than the exhausting performance of the dry pump capable of exhibiting a stable exhausting performance. Therefore, the rotation control is performed on and off, so that the pressure inside the reaction chamber becomes staggering. In particular, in a case where H₂ or the like having a light molecular weight used as a carrier gas in silicon epitaxial growth is discharged using the dry pump, there is a problem in that the exhausting performance falls significantly. This is because H₂ is likely to flow backward through a minute clearance of the dry pump. In this case, the pressure regulation may become unstable further more.

Accordingly, an object of the invention is to provide a vapor growth method and a vapor growth apparatus which can suppress the power consumption of the vacuum pump and stably perform the pressure regulation.

### SUMMARY

A vapor growth apparatus according to an aspect of the present invention includes a reaction chamber into which a wafer is loaded, a gas supply unit which supplies a process gas into the reaction chamber, a supporting unit on which the wafer is placed, a rotation driving unit which rotates the wafer, a heater which heats the wafer to be a predetermined temperature, a first valve which is connected to the reaction chamber and controls a flow rate of a first exhaust gas discharged from the reaction chamber, a first pump which is provided on a downstream side of the first valve and discharges the first exhaust gas, a first pressure gauge which detects a first pressure that is a pressure of the reaction chamber, a first pressure control unit which controls the first valve based on the first pressure, a second pressure gauge which detects a second pressure that is a pressure between the first valve and the first pump, and a second pressure control unit which controls an operation volume of the first pump based on the first pressure and the second pressure.

A vapor growth method according to an aspect of present the invention loads a wafer into a reaction chamber and controls the wafer to be a predetermined temperature, supplies a process gas onto the wafer, controls a flow rate of a first exhaust gas which is discharged from the reaction chamber using a first valve connected to the reaction chamber, discharges the first exhaust gas from the reaction chamber using the first pump which is provided on a downstream side of the first valve, detects a first pressure that is a pressure inside the reaction chamber and a second pressure that is a pressure between the valve and the pump and controls the valve based on the first pressure and controls an operation volume of the pump based on the first pressure and the second pressure.

### BRIEF DESCRIPTION OF THE DRAWINGS

FIG. 1 is a diagram illustrating a configuration of a vapor growth apparatus according to Embodiment 1 of the invention;

FIG. 2 is a cross-sectional view illustrating the vapor growth apparatus illustrated in FIG. 1; and

FIG. 3 is a diagram illustrating a configuration of a vapor growth apparatus according to Embodiment 3 of the invention.

### DETAILED DESCRIPTION

Reference will now be made in detail to the present embodiment of the invention, an example of which is illustrated in the accompanying drawings.

### Embodiment 1

FIG. 1 illustrates the configuration of a vapor growth apparatus of the embodiment. As illustrated in FIG. 1, a reaction chamber 11 in which a wafer w is subjected to a film formation process, a throttle valve 12 which controls a flow rate of an exhaust gas from the reaction chamber 11, and a dry pump 13 which serves as a vacuum pump for discharging the exhaust gas, for example, by rotating a screw rotor are connected to each other sequentially.

Further, a pressure gauge 14a is provided between the reaction chamber 11 and the throttle valve 12 to detect the pressure of the reaction chamber 11. In addition, a pressure gauge 14b is provided between the throttle valve 12 and the dry pump 13 to detect the pressure on the secondary side of the throttle valve 12 (the primary side of the dry pump 13).

Further, the vapor growth apparatus of the present embodiment is provided with a pressure control unit 15a and a pressure control unit 15b. The pressure control unit 15a is connected to the throttle valve 12 and the pressure gauge 14a, and controls the opening of the throttle valve 12 based on the pressure inside the reaction chamber 11. The pressure control unit 15b is connected to the pressure gauges 14a and 14b and the dry pump 13, and controls the rotation frequency of the screw rotor in the dry pump 13 based on the pressure inside the reaction chamber 11 and the pressure on the primary side of the dry pump 13. Further, the pressure control units 15a and 15b may be formed into one body.

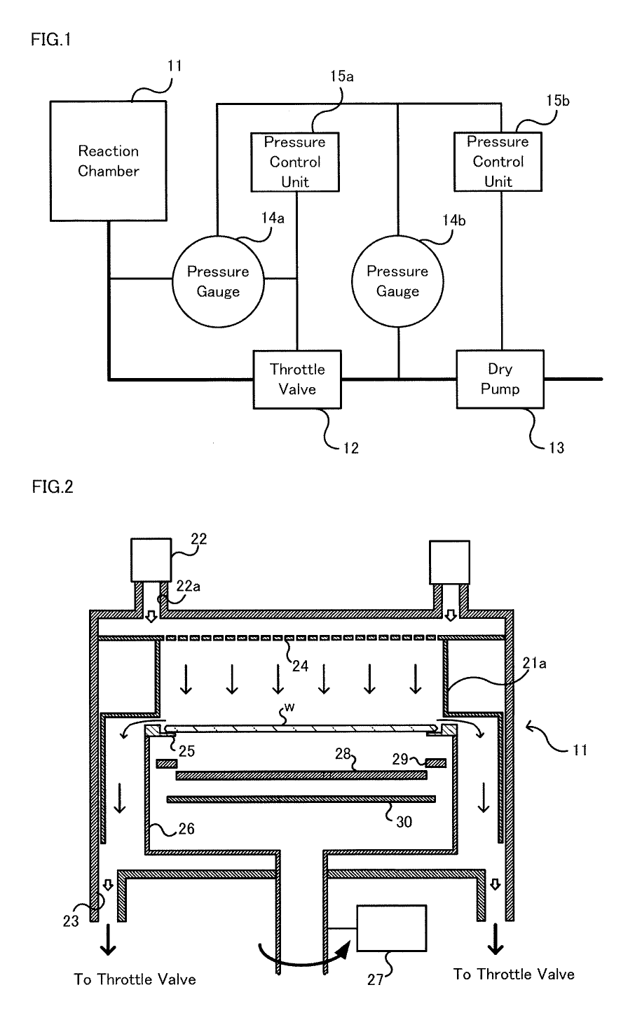

FIG. 2 illustrates a cross-sectional view of the configuration of the reaction chamber 11. The reaction chamber 11 in which the wafer w is subjected to the film formation process is provided with a quartz cover 21a to cover the inner wall thereof as needed.

In the upper portion of the reaction chamber 11, a gas supply port 22a which is connected to a gas supply unit 22 is provided to supply a process gas which includes a source gas and a carrier gas. Further, on the lower side of the reaction chamber 11, for example, two gas discharge ports 23 are provided in different places to be connected to the dry pump 13 through the above-described throttle valve 12.

On the lower side of the gas supply port 22a, a rectifying plate 24 is provided which includes fine through holes for rectifying and supplying the process gas supplied.

Further, on the lower side of the rectifying plate 24, a susceptor 25 made of, for example, SiC is provided which serves as a supporting unit for placing the wafer w. The susceptor 25 is provided on a ring 26 which serves as a rotating member. The ring 26 is connected to a rotation driving unit 27, which includes a motor and the like, through a rotation shaft which rotates the wafer w at a predetermined rotation rate. The rotation driving unit 27 is air-tightly provided in the reaction chamber 11.

In the ring 26, a heater is provided to heat the wafer w, which includes an in-heater 28 and an out-heater 29 made of, for example, SiC, and power is air-tightly supplied thereto through a current introducing terminal (not illustrated). The heater is connected to a temperature control unit (not illustrated) which performs control such that the in-heater 28 and the out-heater 29 each are heated to be a predetermined temperature at a temperature rise/fall rate. Further, on the lower side of the in-heater 28 and the out-heater 29, a disk-shaped reflector 30 is provided to upwardly reflect radiation heat which has been downwardly transferred from the in-heater 28 and the out-heater 29, and to efficiently heat the wafer w.

With the use of such a vapor growth apparatus, a Si-epitaxial film is formed on the wafer w with φ200 mm thick as below.

First, the wafer w is carried in the reaction chamber 11, and placed on the susceptor 25. Then, by causing the temperature control unit to perform control such that the in-heater 28 and the out-heater 29 are heated, for example, to be 1500 to 1600° C., the wafer w is heated, for example, to be 1100° C. Further, the wafer w is rotated, for example, at 900 rpm using the rotation driving unit 27.

Then, a process gas which has been mixed by controlling the flow rate using the gas supply unit 22 is supplied onto the wafer w in a rectified state through the rectifying plate 24. The process gas is supplied such that, for example, 3 SLM of trichlorosilane (SiHCl₃) is included as a source gas and, for example, 70 SLM of H₂ gas is included as a carrier gas.

On the other hand, the exhaust gas including a surplus process gas and react ion by-products are discharged through the gas discharge port 23.

At this time, the flow rate is regulated by controlling the opening of the throttle valve 12 using the pressure control unit 15a, and the rotation frequency of the screw rotor of the dry pump 13 is controlled by the dry pump 13, so that the operation volume of the dry pump 13 is controlled. Then, the control is performed such that the pressure P₁ inside the reaction chamber 11 detected by the pressure gauge 14a becomes, for example, 93.3 kPa, and the pressure (which is the pressure on the primary side of the dry pump) P₂ between the throttle valve 12 and the dry pump 13 detected by the pressure gauge 14b becomes, for example, 45.3 kPa.

In general, the rotation frequency of the screw rotor of the dry pump 13 is constant in a full load state, and a desired pressure can be obtained by controlling the throttle valve 12. However, as described in the present embodiment, in a case where the pressure inside the reaction chamber 11 is near a normal pressure, it is brought into a state where the exhausting performance has plenty of room for margin, and the power may be consumed excessively.

On the other hand, by making the rotation frequency of the screw rotor of the dry pump 13 fall, it is possible to suppress the power consumption caused by excessive operations of the dry pump 13. However, if the rotation frequency of the pump is made to fall too much, the pressure regulation becomes unstable. In particular, as described in the present embodiment, in a case where H₂ or the like having a light molecular weight is used as a carrier gas, the exhausting performance falls significantly. Therefore, the pressure regulation becomes more difficult to be made only by the control of the rotation frequency of the pump.

If the pressure P₂ on the primary side of the dry pump 13 falls within a half of the pressure P₁ of the reaction chamber, the exhausting performance will be sufficiently exhibited. This is because in case where the pressure P₂ falls within a half of the pressure P₁, the pressure P₁ is affected only by the opening of the throttle valve 12, not by the pressure P₂. Herein, since the dry pump 13 is controlled such that the pressure P₂ falls within a half of the pressure P₁, that is, P₂≦P₁/2, the pressure regulation inside of the reaction chamber 11 can be performed stably. Further, the rotation frequency (the operation volume of the dry pump 13) of the screw rotor in the dry pump 13 can be suppressed.

In this way, after the wafer w is formed with the Si-epitaxial film having a predetermined film thickness thereon, the wafer w is unloaded from the reaction chamber 11.

According to the present embodiment, since the operation volume of the dry pump 13 is suppressed based on the pressure inside the reaction chamber 11 and the pressure on the primary side of the dry pump 13, the power consumption of the dry pump 13 at the time of the film formation can be suppressed by about 10% compared with that of, for example, a full load state, and the pressure regulation inside of the reaction chamber 11 can be performed stably.

### Embodiment 2

In the present embodiment, the same vapor growth apparatus of Embodiment 1 is employed, but the film formation is performed under a condition of further lower pressure.

In other words, similarly to Embodiment 1, after the wafer w is carried in the reaction chamber 11 and placed on the susceptor 25, the wafer w is heated, for example, to be 1100° C. Further, the wafer w is rotated, for example, at 900 rpm using the rotation driving unit 27.

Then, a process gas which has been mixed by controlling the flow rate using the gas supply unit 22 is supplied onto the wafer w in a rectified state through the rectifying plate 24. The process gas is supplied such that, for example, 0.3 SLM of dichlorosilane (SiH₂Cl₂) is included as a source gas and, for example, 70 SLM of H₂ gas is included as a carrier gas.

On the other hand, the exhaust gas including a surplus process gas and reaction by-products are discharged through the gas discharge port 23.

At this time, the flow rate is regulated by controlling the opening of the throttle valve 12 using the pressure control unit 15a, and the rotation frequency of the screw rotor of the dry pump 13 is controlled by the dry pump 13, so that the operation volume of the dry pump 13 is controlled. Then, the control is performed such that the pressure P₁ inside the reaction chamber 11 detected by the pressure gauge 14a becomes, for example, 40.0 kPa, and the pressure P₂ between the throttle valve 12 and the dry pump 13 detected by the pressure gauge 14b becomes, for example, 18.7 kPa.

In this way, after the wafer w is formed with the Si-epitaxial film having a predetermined film thickness thereon, the wafer w is unloaded from the reaction chamber 11.

According to the present embodiment, since the operation volume of the dry pump 13 is suppressed based on the pressure on the primary side of the dry pump 13 even though the pressure inside the reaction chamber is a pressure as relatively low as about 40 kPa, the power consumption of the dry pump 13 at the time of the film formation can be suppressed by about 10% compared with that of, for example, a full load state, and the pressure regulation inside of the reaction chamber can be performed stably.

Although it is caused by a gas supply flow rate and the exhausting performance of the pump, when the pressure P₁ inside the reaction chamber 11 becomes low, a difference with the pressure P₂ when the dry pump 13 is operating in the full load state becomes small. The effect of the invention is remarkably exhibited in a pressure of 5 kPa or higher.

### Embodiment 3

In the present embodiment, the same vapor growth apparatus of Embodiment 1 is employed, and a transport chamber which transports a wafer to the reaction chamber is also controlled in pressure.

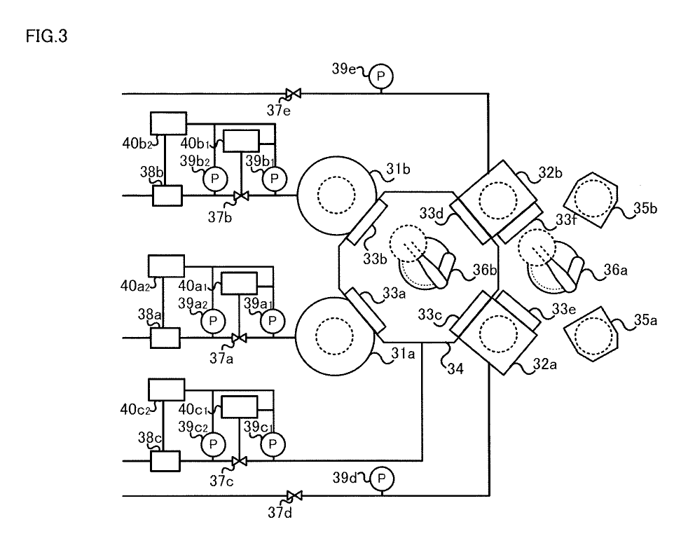

FIG. 3 illustrates the configuration of the vapor growth apparatus of the present embodiment. As illustrated in FIG. 3, reaction chambers 31a and 31b and load lock chambers 32a and 32b respectively are connected to a transport chamber 34 through gate valves 33a, 33b, 33c, and 33d. Further, the load lock chambers 32a and 32b respectively are provided with gate valves 33e and 33f which is used for carrying in/out the wafer w from wafer cassettes 35a and 35b.

Handlers 36a and 36b respectively are provided outside (in the atmosphere) the load lock chambers 32a and 32b and inside the transport chamber 34 to transport the wafer w.

The reaction chambers 31a and 31b respectively are provided with throttle valves 37a and 37b which control the flow rates of the exhaust gases from the reaction chambers 31a and 31b, and dry pumps 38a and 38b which serve as the vacuum pumps discharging the exhaust gases, for example, by rotating screw rotors. Further, pressure gauges 39a₁ and 39b₁ respectively are provided to detect the pressures inside the reaction chambers 31a and 31b.

The reaction chambers 31a and 31b respectively are provided with pressure gauges 39a₂ and 39b₂ which detect the pressures on the secondary sides of the throttle valves 37a and 37b (the primary side of the dry pumps 38a and 38b).

Similarly to Embodiment 1, the reaction chamber 31a is provided with a pressure control unit 40a₁ and a pressure control unit 40a₂. The pressure control unit 40a₁ is connected to the throttle valve 37a and the pressure gauge 39a₁, and controls the opening of the throttle valve 37a based on the pressure inside the reaction chamber 31a. The pressure control unit 40a₂ is connected to the pressure gauges 39a₁ and 39a₂ and the dry pump 38a, and controls the rotation frequency of a screw rotor in the dry pump 38a based on the pressure inside the reaction chamber 31a and the pressure on the secondary side of the throttle valve 37a.

In addition, the reaction chamber 31b is provided with a pressure control unit 40b₁ and a pressure control unit 40b₂. The pressure control unit 40b₁ is connected to the throttle valve 37b and the pressure gauge 39b₁, and controls the opening of the throttle valve 37b based on the pressure inside the reaction chamber 31b. The pressure control unit 40b₂ is connected to the pressure gauges 39b₁ and 39b₂ and the dry pump 38b, and controls the rotation frequency of a screw rotor in the dry pump 38b based on the pressure inside the reaction chamber 31b and the pressure on the secondary side of the throttle valve 37b.

In addition, similarly to the reaction chambers 31a and 31b, the transport chamber 34 is provided with a throttle valve 37c which controls the flow rate of the exhaust gas from the transport chamber 34 and a dry pump 38c which serves as a vacuum pump discharging the exhaust gas, for example, by rotating a screw rotor. Further, a pressure gauge 39c₁ is provided to detect the pressure P₃ inside the transport chamber 34.

In addition, the transport chamber 34 is provided with a pressure gauge 39c₂ which detects the pressure P₄ on the secondary side of the throttle valve 37c (the primary side of the dry pump 38c).

Further, the transport chamber 34 is provided with a pressure control unit 40c₁ and a pressure control unit 40c₂. The pressure control unit 40c₁ is connected to the throttle valve 37c and the pressure gauge 39c₁, and controls the opening of the throttle valve 37c based on the pressure P₃ of the transport chamber 34. The pressure control unit 40c₂ is connected to the pressure gauges 39c₁ and 39c₂ and the dry pump 38c, and controls the rotation frequency of the screw rotor in dry pump 38c based on the pressure P₄ on the primary side of the dry pump 38c and the pressure P₃ of the transport chamber 34.

If the pressure P₄ on the primary side of the dry pump 38c falls within a half of the pressure P₃ inside the transport chamber 34, the exhausting performance will be sufficiently exhibiting. Herein, since the dry pump 38c is controlled such that the pressure P₄ falls within a half of the pressure P₃, that is, P₄≦P₃/2, the pressure regulation inside of the transport chamber 34 can be performed stably. Further, the rotation frequency (the operation volume of the dry pump 38c) of the screw rotor in the dry pump 38c can be suppressed.

The load lock chambers 32a and 32b respectively are provided with throttle valves 37d and 37e which control the flow rates of the exhaust gases. Further, the load lock chambers 32a and 32b respectively are provided with pressure gauges 39d and 39e which detect the pressures in the load lock chambers 32a and 32b.

Further, the pressure control units 40a₁ and 40a₂, the pressure control units 40b₁ and 40b₂, and the pressure control units 40c₁ and 40c₂ may be formed into one body, respectively.

With the use of such a vapor growth apparatus, the film formation process is performed on the wafer w as described below.

Preliminarily, the transport chamber 34 is supplied with 5 SLM of H₂ using a Mass Flow Controller (MFC) (not illustrated). The transport chamber 34 is controlled such that the pressure measured by the pressure gauge 39c₁ becomes 93.3 kPa and the pressure on the secondary side of the throttle valve 37c (the primary side of the dry pump 38c) which is measured by the pressure gauge 39c₂ becomes 45.3 kPa.

Hereinafter, the description will be made only about the reaction chamber 31a and the load lock chamber 32a, but the reaction chamber 31b and the load lock chamber 32b are controlled in the same way.

First, the wafer w is taken out from the wafer cassette 35a by the handler 36a. After the wafer w is subjected to a notch alignment, the gate valve 33e is opened. Then, the wafer w is transported to the load lock chamber 32a in which the pressure measured by the pressure gauge 39d has been previously controlled to be in an atmospheric pressure (101.3 kPa) state.

After the gate valve 33e is closed and the load lock chamber 32a is vacuumized, H₂ is supplied to make the pressure become 93.3 kPa.

The gate valve 33c is opened to transport the wafer w to the transport chamber 34 using the handler 36b, and the gate valve 33c is closed. Then, the gate valve 33a is opened to transport the wafer w to the reaction chamber 31a of which the pressure has been previously controlled to become 93.3 kPa using the handler 36b, and the gate valve 33a is closed.

In this way, after the wafer w transported to the reaction chamber 31a is subjected to the film formation process similar to Embodiments 1 and 2, the gate valve 33a is opened to carry out the wafer w through the transport chamber 34 and the load lock chamber 32a.

According to the transport chamber 34 of the present embodiment, similarly to Embodiments 1 and 2, the operation volume of the dry pump 38c is suppressed based on the pressure inside the transport chamber 34 and the pressure on the primary side of the dry pump 38c. Therefore, the power consumption of the dry pump 38c provided in the transport chamber 34 can be suppressed by 10% compared with that of, for example, a full load state, and the pressure regulation inside of the transport chamber 34 can be performed stably.

According to these embodiments described above, the power consumption of the vacuum pumps in the reaction chamber and the transport chamber can be suppressed, and the pressure regulation can be performed stably, thereby forming a film such as an epitaxial film on the semiconductor wafer w with high productivity. Further, an increase in a yield of wafers, an increase in a yield of semiconductor elements through an element forming process and an element separation process, and the stability of element characteristics can be achieved. In particular, these embodiments described above may be applied to the epitaxial growth process of power semiconductor devices such as power MOSFETs and IGBTs, in which a thick film of 100 μm or more is necessarily grown in an N-type base region, a P-type base region, an insulating separation region, and the like, so that good element characteristics can be achieved.

In addition, the case of the Si-epitaxial film formation has been exemplified in these embodiments described above. However, these embodiments can be applied at the time of forming: epitaxial layers of compound semiconductors, for example, GaN, SiC, InGaP, GaAlAs, and InGaAsP; a poly-Si layer; and an insulating film of, for example, SiO₂ layer, Si₃N₄ layer, and the like. Furthermore, various modifications can be implemented without departing from the scope of the invention.

What is claimed is:

1. A vapor growth apparatus comprising:
a reaction chamber into which a wafer is loaded;
a gas supply unit which supplies a process gas into the reaction chamber;
a supporting unit on which the wafer is placed;
a rotation driving unit which rotates the wafer;
a heater which heats the wafer to be a predetermined temperature;
a first valve which is connected to the reaction chamber and controls a flow rate of a first exhaust gas discharged from the reaction chamber;
a first pump which is provided on a downstream side of the first valve and discharges the first exhaust gas;
a first pressure gauge which detects a first pressure that is a pressure of the reaction chamber;
a first pressure control unit which controls the first valve based on the first pressure;
a second pressure gauge which detects a second pressure that is a pressure between the first valve and the first pump; and
a second pressure control unit which controls an operation volume of the first pump based on the first pressure and the second pressure.

2. The vapor growth apparatus according to claim 1, wherein the second pressure control unit controls the operation volume of the first pump such that the second pressure falls within a half of the first pressure.

3. The vapor growth apparatus according to claim 2, wherein the first exhaust gas includes H₂.

4. The vapor growth apparatus according to claim 3, wherein the first pump is a dry pump.

5. The vapor growth apparatus according to claim 4, wherein the first pressure control unit controls the first valve such that the first pressure becomes 5 kPa or higher.

6. The vapor growth apparatus according to claim 2, further comprising:
a transport chamber which transports the wafer to the reaction chamber;
a second valve which is connected to the transport chamber and controls a flow rate of a second exhaust gas discharged from the transport chamber;
a second pump which is provided on a downstream side of the second valve and discharges the second exhaust gas;
a third pressure gauge which detects a third pressure that is a pressure of the transport chamber;
a fourth pressure gauge which detects a fourth pressure that is a pressure between the second valve and the second pump;
a third pressure control unit which controls the second valve based on the third pressure; and
a fourth pressure control unit which controls an operation volume of the second pump based on the third pressure and the fourth pressure.

7. The vapor growth apparatus according to claim 6, wherein the fourth pressure control unit controls the operation volume of the second pump such that the fourth pressure falls within a half of the third pressure.

8. The vapor growth apparatus according to claim 7, wherein the first and second exhaust gases include H₂.

9. The vapor growth apparatus according to claim 8, wherein the first and second pumps are dry pumps.

10. The vapor growth apparatus according to claim 9, wherein the first pressure control unit controls the first valve such that the first pressure becomes 5 kPa or higher.

11. The vapor growth apparatus according to claim 1, further comprising:
a transport chamber which transports the wafer to the reaction chamber;
a second valve which is connected to the transport chamber and controls a flow rate of a second exhaust gas discharged from the transport chamber;
a second pump which is provided on a downstream side of the second valve and discharges the second exhaust gas;
a third pressure gauge which detects a third pressure that is a pressure of the transport chamber;
a fourth pressure gauge which detects a fourth pressure that is a pressure between the second valve and the second pump;
a third pressure control unit which controls the second valve based on the third pressure; and
a fourth pressure control unit which controls an operation volume of the second pump based on the third pressure and the fourth pressure.

12. The vapor growth apparatus according to claim 11, wherein the first and second exhaust gases include H₂.

13. The vapor growth apparatus according to claim 12, wherein the first and second pumps are dry pumps.

14. A vapor growth apparatus comprising:
a reaction chamber into which a wafer is loaded;
a gas supply unit which supplies a process gas into the reaction chamber;
a susceptor on which the wafer is placed;
a rotation driving unit which rotates the wafer;
a heater which heats the wafer to be a predetermined temperature;
a first valve which is connected to the reaction chamber and controls a flow rate of an exhaust gas discharged from the reaction chamber;
a dry pump which is provided on a downstream side of the first valve and discharges the exhaust gas;
a first pressure gauge which detects a first pressure that is a pressure of the reaction chamber;
a first pressure control unit which controls the first valve based on the first pressure;
a second pressure gauge which detects a second pressure that is a pressure between the first valve and the first pump; and
a second pressure control unit which controls an operation volume of the dry pump such that the second pressure falls within a half of the first pressure.

15. A vapor growth method comprising:
loading a wafer into a reaction chamber and controlling the wafer to be a predetermined temperature;
supplying a process gas onto the wafer;
controlling a flow rate of a first exhaust gas which is discharged from the reaction chamber using a first valve connected to the reaction chamber;
discharging the first exhaust gas from the reaction chamber using the first pump which is provided on a downstream side of the first valve;
detecting a first pressure that is a pressure inside the reaction chamber and a second pressure that is a pressure between the first valve and the first pump; and
controlling the first valve based on the first pressure and controlling an operation volume of the first pump based on the first pressure and the second pressure.

16. The vapor growth method according to claim 15, wherein the operation volume of the first pump is controlled such that the second pressure falls within a half of the first pressure.

17. The vapor growth method according to claim 16, further comprising:
loading the wafer into a transport chamber which is adjacent to the reaction chamber;
controlling a flow rate of a second exhaust gas which is discharged from the transport chamber using a second valve connected to the transport chamber;
discharging the second exhaust gas from the transport chamber using the second pump which is provided on a downstream side of the second valve;
detecting a third pressure that is a pressure of the transport chamber using a third pressure gauge;
detecting a fourth pressure that is a pressure between the second valve and the second pump using a fourth pressure gauge;
controlling the second valve based on the third pressure; and
controlling an operation volume of the second pump based on the third pressure and the fourth pressure.

18. The vapor growth method according to claim 17, wherein the operation volume of the second pump is controlled such that the fourth pressure falls within a half of the third pressure.

19. The vapor growth method according to claim 18, wherein the first and second exhaust gases include H₂.

20. The vapor growth method according to claim 19, wherein the first valve is controlled such that the first pressure becomes 5 kPa or higher.
